(19) United States
(12) Patent Application Publication
(10) Pub. No.: US 2010/0304143 A1
(43) Pub. Date: Dec. 2, 2010

(54) PRODUCTION OF Si02-COATED TITANIUM DIOXIDE PARTICLES WITH AN ADJUSTABLE COATING

(75) Inventors: Alexandra Seeber, Mannheim (DE); Götz-Peter Schindler, Ludwigshafen (DE); Katrin Freitag, Ludwigshafen (DE); Frank Jäger, Bad Dürkheim (DE); Dirk Klingler, Mannheim (DE); Frieder Borgmeier, Mannheim (DE)

Correspondence Address: CONNOLLY BOVE LODGE & HUTZ, LLP, P O BOX 2207, WILMINGTON, DE, 19899, US

(73) Assignee: BASF SE, Ludwigshafen (DE)

(21) Appl. No.: 12/675,432

(22) PCT Filed: Aug. 27, 2008
(86) PCT No.: PCT/EP2008/061221

§ 371 Date: Feb. 26, 2010

(30) Foreign Application Priority Data
Aug. 28, 2007 (EP) 07115104.7

(51) Int. Cl. B32B 1/00; B05D 7/00; C23C 16/44

(52) U.S. Cl. 428/404; 427/212; 428/403; 427/215; 118/716

(57) ABSTRACT

The present invention relates to a process for producing coated nanoparticles comprising a core comprising at least one first substance and at least one envelope at least partly surrounding the core and composed of at least one further substance, in a streaming system, to nanoparticles which can be produced according to this process, to nanoparticles comprising a nonporous core comprising at least one first substance and at least one porous envelope at least partly surrounding the core and composed of at least one further substance, the nanoparticles having a narrow particle size distribution, to the use of such nanoparticles in photocatalysis and to apparatus for carrying out the process.

The present invention relates to a process for producing coated nanoparticles comprising a core comprising at least one first substance and at least one envelope at least partly surrounding the core and composed of at least one second substance, to nanoparticles comprising a nonporous core comprising at least one first substance and at least one porous envelope at least partly surrounding the core and composed of at least one second substance, the nanoparticles having a narrow particle size distribution, to the use of such nanoparticles in photocatalysis and to apparatus for carrying out the present invention's process.

Nanoparticles comprising a core composed of at least one metal oxide and an envelope composed of at least one further metal or semimetal oxide and also processes for their production are already known from the prior art.

WO 2005/113442 A1 discloses a process for producing mixed ternary metal or semimetal oxide powders comprising mixing vaporizable silicon and titanium compounds and a third vaporizable compound, hydrogen and air and burning this gaseous mixture in a reaction space, removing the resulting powder from the gaseous reaction products. The ternary mixed metal oxide powder thus obtained can be used in sunscreen formulations. WO 2005/113442 A1 discloses a process for producing mixed oxide particles in which the individual oxides are present in admixture throughout the entire particle; the process described in WO 2005/113442 A1 does not give a layered structure.

US 2006/0093544 A1 discloses a method of preparing composite microparticles having a thin coating by reacting a core particle precursor in vaporized or micronized form to obtain the corresponding core particles. Subsequently, a gaseous coating precursor is introduced concurrently toward the core particles to form the coating. US 2006/0093544 A1 does not disclose a method of obtaining nanoparticles in a narrow particle size distribution, or of adjusting the thickness of the coating on the particles. Nor does the cited reference disclose a method of obtaining a porous coating on a nonporous core.

EP 1 138 632 A1 discloses a process for producing doped titanium dioxide wherein an aerosol comprising precursor compounds for of compounds selected from the group consisting of zinc oxide, platinum oxide, magnesium oxide and/or aluminum oxide is homogeneously admixed to the gas mixture of the flame oxidation to produce titanium dioxide, the aerosol/gas mixture is reacted in a flame and the resulting doped oxides produced are separated from the gas stream in a known manner. The mixed oxide particles thus obtained comprise a homogeneous distribution of titanium dioxide and the further oxide in the particle. A layered structure comprising a core and at least one envelope cannot be obtained via the process described in EP 1 138 632 A1.

JP 2001/286728 discloses a process for producing photocatalysts coated with a layer of a porous ceramic. The coating contains pores to maintain the function of the catalyst and also to avoid the degradation of any organic material in contact with the photocatalyst. The process for producing these particles comprises coating photocatalysts with a film of the porous ceramic by hydrophilicizing a metal alkoxide as a precursor compound of the ceramic with a polyhydric alcohol, addition of water and photocatalyst to this mixture and spray drying of this mixture to obtain a powder which is finally dried. The process disclosed in JP 2001/286728 scarcely permits influencing coating thickness. Nor does the cited reference disclose a process whereby coated nanoparticles are obtained in a narrow particle size distribution.

JP2003-001118 A discloses photocatalytically active nanoparticles consisting of a titanium dioxide core and an incomplete envelope of SiO₂. This document does not disclose any nanoparticles having an activity that is specifically adjustable via envelope thickness and envelope porosity.

It is an object of the present invention to provide a process for producing coated nanoparticles which makes it possible to obtain core-envelope nanoparticles having a narrow particle size distribution. It shall further be possible to obtain nanoparticles having a thin, porous envelope whose thickness, and hence the catalytic activity of the substance present in the nonporous core, can be specifically adjusted.

We have found that this object is achieved according to the present invention by a process for producing coated nanoparticles comprising a core composed of at least one first substance and at least one envelope at least partly surrounding the core and composed of at least one second substance, in a streaming system, said process comprising the steps of:
(A) providing a main stream composed of a reaction gas or aerosol comprising at least one precursor compound of the at least one first substance present in the core of the coated nanoparticle,
(B) converting by thermal reaction in the main stream the at least one precursor compound present in the reaction gas or aerosol of step (A) into the corresponding at least one first substance to form the core of the nanoparticles to be produced,
(C) adding in a cross stream with regard to the main stream from step (B) a further reaction gas or aerosol comprising at least one precursor compound of the at least one second substance present in the at least one envelope,
(D) converting by thermal reaction in the main stream the at least one precursor compound present in the reaction gas or aerosol of step (C) into the corresponding at least one second substance to form the at least one envelope of the nanoparticles to be produced, and
(E) rapidly cooling the nanoparticles obtained in step (D), by adding a coolant to the main stream.

We have found that the object is further achieved by nanoparticles comprising a nonporous core composed of at least one first substance and at least one porous envelope at least partly surrounding the core and composed of at least one second substance, the nanoparticles having a narrow particle size distribution, by the use of such nanoparticles in photocatalysis and by an apparatus for carrying out the present invention's process.

The individual steps of the present invention's process will now be described:

### Step (A):

The present invention's process for producing coated nanoparticles comprising a core composed of at least one first substance and at least one envelope at least partly surrounding the core and composed of at least one second substance, in a streaming system, said process comprising as step (A):
(A) providing a main stream composed of a reaction gas or aerosol comprising at least one precursor compound of the at least one first substance present in the core of the coated nanoparticle.

In general, any precursor compound to the first substance can be utilized in step (A) that is transformable into the corresponding substance by thermal treatment.

In a preferred embodiment of the present invention's process, the core of the nanoparticles comprises at least one metal or semimetal oxide and the at least one envelope of the nanoparticle comprises at least one further metal or semimetal oxide.

Inorganic and organic compounds can be used as a precursor compound to the at least one metal or semimetal oxide present in the core of the present invention's coated nanoparticle.

Suitable metals or semimetals whose oxides are present in the core of the present invention's nanoparticles and whose corresponding precursor compounds are used in step (A) are generally selected from the group consisting of elements of groups 1 to 15 of the periodic table (in accordance with IUPAC), lanthanides, actinides and mixtures thereof, preferably from the group consisting of V, Ti, Zr, Ce, Mo, Bi, Zn, Mn, Si, Ba, Au, Ag, Pd, Pt, Ru, Rh, La and mixtures thereof.

Useful inorganic precursor compounds include for example the halogens, preferably the chlorides, carbonates, nitrates of the corresponding metals or semimetals and the corresponding pure metals or semimetals while useful organic precursor compounds include for example salts of the corresponding metals with alcohols having 1 to 8 carbon atoms, for example methanol, ethanol, n-propanol, isopropanol, tert-butanol and mixtures thereof. Useful organic precursor compounds further include organometal complexes.

Particularly useful as precursor compounds of the at least one metal or semimetal oxide on the core of the coated nanoparticle are titanium tetrachloride (TiCl₄), silicon tetrachloride (SiCl₄), tetraisopropyl orthotitanate, siloxanes such as hexamethyl-disiloxane and mixtures thereof. TiCl₄ or SiCl₄ is preferably used when the present invention's process is conducted on a large industrial scale. When the present invention's process is conducted on the lab or pilot plant scale, tetraisopropyl orthotitanate or siloxanes such as hexamethyldisiloxane are preferably used. Therefore, TiO₂ is a particularly preferred metal or semimetal oxide forming the core of the nanoparticles, and it is preferably more than 50% and more preferably 60 to 65% in the anatase form.

The reaction gas in step (A) is obtained by vaporizing or evaporating the at least one precursor compound by a process known to one skilled in the art. The vaporization temperature depends on the boiling temperature of the precursor compound to be vaporized. The vaporizing or evaporating of the corresponding precursor compound can be carried out in an inert atmosphere, for example in nitrogen or a noble gas. The vaporizing or evaporating can take place under atmospheric pressure or under a pressure below atmospheric pressure. When the vaporizing or evaporating takes place at a pressure below atmospheric pressure, the chosen temperature can be appropriately lower. Alternatively, the precursor compound can also be vaporized or evaporated at higher pressure by raising the temperature.

The precursor compound can also be in solution. Useful solvents include the solvents mentioned hereinbelow as fuels.

Step (A) of the present invention's process may also utilize a reaction aerosol. Herein, an aerosol is a fine distribution of liquid droplets of mist in a gaseous medium. The aerosol used in step (A) is obtainable by misting the at least one precursor compound of the metal or semimetal oxide present in the core, or a solution thereof, via processes known to one skilled in the art. Such processes include for example atomization through one-material or multi-material nozzles or ultrasonic atomizers. Inert gases such as nitrogen, noble gases, oxygen or air or mixtures thereof can serve as gaseous carrier for the aerosol. The carrier gas can also be a combustible gas which serves as a fuel in step (B) of the present invention's process for example.

The reaction gas or aerosol in step (A) may be admixed with a fuel, if appropriate. This fuel may be gaseous under the reaction conditions or, when an aerosol is used, be present as a finely divided liquid mist. In general, any compound can be used as a fuel that is liquid or gaseous under the conditions of the present invention's process and enters an exothermic reaction with oxygen under the conditions of the present invention's process. Useful fuels include for example hydrogen, carbon monoxide or hydrocarbons such as methane, ethylene, organic solvents such as xylene, toluene, benzene or mixtures thereof. When the present invention's process is practiced on a large industrial scale, hydrogen is a preferred fuel.

Step (A) of the present invention's process comprises providing a main stream composed of the abovementioned reaction gas or aerosol. This main stream is preferably provided in a tubular reactor wherein the main stream flows from the reactor inlet to the reactor outlet. The reactions leading to the formation of the present invention's core-envelope nanoparticles are carried out while the substrates and products of the individual process steps move with the main stream.

In a preferred embodiment, the providing of the main stream in step (A) can be accomplished by the present components being introduced, via a mixing appliance, in the gaseous, vaporized, misted or liquid state into the reactor and mixed therein. The pressure at which the reaction mixture is introduced into the reactor is generally up to 10 bar (gaseous precursor) or up to 100 bar (liquid precursor).

In a further preferred embodiment, a second gas stream, this gas stream comprising oxygen, is at the same time fed concurrently or transversely to the stream comprising the reaction gas or aerosol. This second stream may comprise pure oxygen or a mixture of oxygen and further components, examples of further components being nitrogen or other inert gases. Air can also be used.

### Step (B):

Step (B) of the present invention's process comprises
(B) converting by thermal reaction in the main stream the at least one precursor compound present in the reaction gas or aerosol of step (A) into the corresponding at least one first substance to form the core of the nanoparticles to be produced.

In step (B) of the present invention's process, the precursor compound of the first substance present in the core is converted into the corresponding substance via thermal treatment. The oxidizable compounds supplied in (A) are used as a fuel in step (B). The energy created on burning this fuel is used to convert the precursor compound into the corresponding substance, preferably the corresponding oxide.

Step (B) comprises forming the core of the nanoparticle to be produced according to the present invention while the main stream is moving through the tubular reactor. In one preferred embodiment, the stream composed of a reaction gas or aerosol has a residence time in the reaction zone i.e. in the zone in which the thermal conversion of the precursor compound into the corresponding preferred metal or semimetal oxide present in the core takes place, of 1 to 1000 ms, more preferably 1 to 100 ms and most preferably 1 to 50 ms.

The temperature in the reaction zone is preferably in the range from 600 to 2500° C. and more preferably in the range from 800 to 1800° C. In one preferred embodiment, the temperature is constant in the entire reaction zone.

Because the residence time in the hot reaction zone is particularly accurately adjustable according to the present invention the cores of the present invention's nanoparticles are obtained in a very uniform primary particle size of preferably not more than 1 μm, more preferably in the range from 1 to 200 nm and most preferably in the range from 5 to 40 nm. This is the basis for the narrow particle size distribution of the nanoparticles according to the present invention compared with other nanoparticles produced by flame synthesis. Furthermore, the cores produced according to the present invention are nonporous in one preferred embodiment.
Step (C):

Step (C) of the present invention's process comprises
(C) adding in a cross stream with regard to the main stream from step (B) a further reaction gas or aerosol comprising at least one precursor compound of the at least one second substance present in the at least one envelope.

Step (C) of the present invention's process comprises adding to the main stream from step (B) a further reaction gas or aerosol comprising the cores of the nanoparticle which is to be produced that have been produced in step (B) by thermal reaction of the corresponding precursor compounds in the streaming system. The further reaction gas or aerosol comprises at least one precursor compound of the at least one second substance present in the at least one envelope of the nanoparticle obtainable according to the present invention. In one preferred embodiment, the nanoparticle produced according to the present invention has one envelope.

The delay time between metered addition of the core material precursor at the main nozzle in step (A) and the addition of the coating material precursor in step (C) is preferably in the range from 1 to 1000 ms, more preferably in the range from 1 to 100 ms and most preferably in the range from 1 to 20 ms.

Preferred precursor compounds to form the at least one envelope of the nanoparticle obtainable according to the present invention comprise compounds comprising elements of groups 1 to 15 of the periodic table (in accordance with IUPAC), lanthanides, actinides and mixtures thereof, preferably selected from the group consisting of V, Ti, Zr, Ce, Mo, Bi, Zn, Mn, Si, Ba, Au, Ag, Pd, Pt, Ru, Rh, La and mixtures thereof. Ti and Si are very particularly preferred.

The metals and semimetals mentioned are present in inorganic or organic compounds or as mixtures of the two. Suitable precursor compounds are subject to the remarks made with regard to the precursor compounds for the metal or semimetal oxide present in the core of the present invention's particle.

One preferred embodiment utilizes titanium tetrachloride (TiCl₄) or silicon chloride (SiCl₄) as inorganic precursor compounds in step (C). A further preferred embodiment utilizes tetraisopropyl orthotitanate (TTiP) or hexamethyldisiloxane (HMDS) as organic precursor compounds. When the process is carried out on a large industrial scale, TiCl₄ and SiCl₄ are preferred. When the process is carried out on the lab or pilot plant scale, tetraisopropyl orthotitanate or hexamethyldisiloxane are preferred precursor compounds.

SiO₂, ZnO, CeO₂, TiO₂ or SnO are particularly preferred oxides.

The reaction gas or aerosol can be generated in the same way as already described with regard to step (A) of the present invention's process.

Step (C) comprises adding this second reaction gas or aerosol at one or more circumferentially distributed locations in a cross stream with regard to the main stream generated in steps (A) and (B). This, in one preferred embodiment, can take place via appropriate inlets or nozzles in the tubular reactor. Cross stream herein is to be understood as meaning that the reaction gas or aerosol impinges on the main stream, comprising the cores formed in step (B) of the nanoparticle to be produced, at an angle α of 45 to 135°, preferably 60 to 120°. The tangential angle of pitch β in the equatorial plane relative to the main stream is in the range from −90 to +90°, preferably −30 to +30°.

Because the envelope precursor compound is supplied in a cross stream with regard to the main stream, the mixing time between the core and the coating precursor compound is very short, ensuring that the core is surrounded by a homogeneous concentration of the precursor compound and a very uniform porous envelope is formed. Furthermore, the coating layer thickness can be varied by varying the concentration of the coating precursor compound. Thus, the present invention's process makes it possible to produce coated nanoparticles having a narrow distribution with regard to particle size and also a very narrow distribution with regard to coating layer thickness. The narrowness of the particle size distribution is evident from FIG. 2.

### Step (D):

Step (D) of the present invention's process comprises
(D) converting by thermal reaction in the main stream the at least one precursor compound present in the reaction gas or aerosol of step (C) into the corresponding at least one second substance to form the at least one envelope of the nanoparticles to be produced.

So the at least one compound applied to the core in step (C) as a precursor to the at least one second substance, preferably at least one metal or semimetal oxide present in the at least one envelope, is converted into the corresponding substance, preferably into the metal or semimetal oxide, in step (D) to form the at least one envelope of the nanoparticle to be produced. This converting is accomplished according to the present invention by subjecting the precursor compounds to a thermal reaction in which the substantially isothermal reaction regime makes it possible to develop a very homogeneous distribution for the layer thicknesses of the envelope.

The at least one envelope of the nanoparticle is formed in step (D), so that the present invention's nanoparticle consists of a core and an envelope at least partly surrounding this core. The envelope is preferably porous and preferably has a layer thickness of not more than 10 nm, more preferably 0.1 to 3 nm.

### Step (E):

Step (E) of the present invention's process comprises
(E) rapidly cooling the nanoparticles obtained in step (D), by adding a coolant.

The nanoparticle comprising a core and at least one envelope and obtained in step (D) is very rapidly cooled down in step (E) by addition of coolant.

The rate of cooling in step (E) is preferably at least 10⁴ K*s⁻¹, more preferably at least 10⁵ K*s⁻¹ and most preferably at least 5*10⁵ K*s⁻¹.

The cooling (quenching) in step (E) is carried out such that the temperature of the reaction mixture in the main stream after step (E) is below the melting point of core and shell material, preferably <800° C., more preferably <400° C. and most preferably <200° C.

In one preferred embodiment, the coolant in step (E) of the present invention's process is a gas or a liquid. Useful quenching gases are preferably selected from the group consisting of air, nitrogen or other inert gases and mixtures thereof. In another preferred embodiment, useful quenching liquids are selected from liquid nitrogen, organic solvents, for example diethylene glycol dimethyl ether, paraffin oil (white oil), tetrahydrofuran, naphtha, soybean oil, water or mixtures thereof. In a particularly preferred embodiment, these organic solvents are sprayed in liquid form into the main stream.

The quenching liquid may preferably be added via appropriate inlets or nozzles. The quenching liquid can be added at an angle α′ of 45 to 135°, preferably 60 to 120° relative to the main stream; the angle of pitch β′ in the equatorial plane relative to the main stream is in the range from −90 to +90°, preferably −30 to +30°.

Step (E) may optionally be followed by a further step comprising the metered addition of an organic substance to surface-modify the resulting coated nanoparticles from step (E). Useful surface-modifying substances include anionic, cationic, amphoteric or nonionic surfactants, for example Lutensol®, dispersants having a molar mass of 2 to 20 000 g/mol, for example Sokalan® or substances for chemical surface functionalization, and also any desired combinations thereof.

These organic substances can selectively also be used directly as a quenching liquid in step (E), or can be added to the abovementioned quenching liquids, so that they are added directly in step (E).

In a further preferred embodiment of the present invention's process, the nanoparticles obtained after step (E) are separated off as a powder or as a dispersion.

In one preferred embodiment, the present invention's process is followed by a step of separating the coated nanoparticles from gaseous impurities by a filter or cyclone.

The present invention accordingly also provides nanoparticles having a narrow particle size distribution for flame synthesis and obtainable by the present invention's process. In a narrow particle size distribution for the purposes of the present invention, preferably ≧70%, more preferably ≧80% and most preferably ≧90% of the particle sizes are within just 20, preferably 15 and more preferably 10 nm of the average particle size.

The core-envelope nanoparticles obtained via the present invention's process have a nonporous core and a porous coating. Because coating thickness and porosity are specifically adjustable via the various process parameters, the catalytic activity of the core is specifically adjustable to the corresponding requirements.

The present invention also provides nanoparticles comprising a nonporous core composed of at least one first substance and at least one porous envelope at least partly surrounding the core and composed of at least one second substance, characterized by their ratio of more than 1.8 for their photoactivity with regard to noxiant degradation to photoactivity with regard to polymer degradation.

Photoactivity against fluidic noxiants is preferably more than 60% of the photoactivity of a standard photocatalyst (Degussa P25), more preferably more than 70% and most preferably more than 80%. Photoactivity against fixed matrices is preferably less than 65% of the photoactivity of a standard photocatalyst (Degussa P25), more preferably less than 60% and most preferably less than 55%.

The ratio of photoactivity with regard to noxiant degradation to photoactivity with regard to polymer degradation is more than 1.8, preferably more than 2 and more preferably more than 2.5.

The materials in the core and envelope of the present invention's nanoparticles are subject to the remarks made with regard to their process of production.

In one preferred embodiment, the nonporous core of the present invention's nanoparticle consists of TiO₂ and the porous envelope consists of SiO₂. The TiO₂ present in the core of the nanoparticle is preferably more than 80% and more preferably 90 to 95% in the anatase form.

The core of the present invention's nanoparticle has a diameter of preferably not more than 1 μm and the envelope of the nanoparticle has a thickness of not more than 10 nm. In one preferred embodiment, core diameter is in the range from 1 to 200 nm and more preferably in the range from 5 to 40 nm. In a further preferred embodiment, envelope layer thickness is in the range from 0.1 to 10 nm and more preferably in the range from 0.1 to 3 nm.

The porosity of the envelope of these nanoparticles obtained according to the present invention can be expressed in terms of the ratio of the proportion of silicon in atom % to titanium in atom % and is in the range from 2 to 80, more preferably in the range from 5 to 60, more preferably in the range from 8 to 40, all measured via XPS (X-Ray Photo Electron Spectroscopy—ESCA Electron Spectroscopy for Chemical Analysis).

The present invention also provides for the use of these nanoparticles in photocatalysis.

The present invention further also provides apparatus for carrying out the invention's process, comprising in a tubular reactor
a unit for feeding the reaction gas or aerosol comprising at least one precursor compound of the at least one first substance present in the core and forming a main stream in the tubular reactor,
a unit for thermally reacting the at least one precursor compound present in this reaction gas to convert it into the at least one first substance present in the core,
a unit for feeding the reaction gas or aerosol comprising at least one precursor compound of the at least one second substance present in the at least one envelope, in a cross stream with regard to the main stream, and
a unit for rapidly cooling the nanoparticle obtained.

In one preferred embodiment, the diameter to length ratio for the tubular reaction space in the present invention's apparatus is in the range from ½ to 1/10 and more preferably in the range from ¼ to ⅙.

Suitable units for feeding the reaction gas or aerosol comprising at least one precursor compound of the at least one first substance present in the core and for forming a main stream in the tubular housing are selected from the group consisting of two-material nozzles, homogeneous devices for mixing. These units mentioned are able to mix the corresponding precursor compound and if appropriate fuels in the form of gases or in the form of mists of liquid and if appropriate further gaseous components, for example an O₂-containing gas, and to generate a main stream by injection into the reactor.

The unit for thermal conversion of the at least one precursor compound present in this reaction gas to the at least one substance present in the core is preferably constructed such that burning the mixture comprising the precursor compound of the metal or semimetal oxide of the core generates sufficient thermal energy to effectuate the conversion of the precursor compound into the corresponding substance, preferably the corresponding oxide, with simultaneous formation of the nanoparticles. According to the present invention, the reactor is—with the exception of the cooling location—under the same temperature, preferably 600 to 2500° C., more preferably 800 to 1800° C. This consistent temperature makes it possible to form nanoparticles having a narrow particle size distribution.

In the present invention's reactor, the unit for thermally reacting the precursor compounds which form the substance present in the core is preferably a path section of the main stream generated at the beginning. The substance, preferably the oxide, of the core is formed in the reaction zone, along the main stream. The present invention's reactor is configured such that the residence time in the zone in which the cores are formed is preferably in the range from 1 to 1000 ms, more preferably in the range from 1 to 100 ms and most preferably in the range from 1 to 50 ms.

The unit for feeding the reaction gas or aerosol comprising at least one precursor compound of the at least one second substance present in the at least one envelope in a cross stream with regard to the main stream is preferably configured such that the inside surface of the tubular reactor is fitted with nozzles allowing the reaction gas or aerosol to impinge on the main stream at an angle α of preferably 45 to 135°, more preferably 60 to 120°.

The unit for rapidly cooling the resulting nanoparticles in the present invention's apparatus is preferably engineered so as to obtain cooling rates of greater than 10⁴ K*s⁻¹, preferably 10⁵ K*s⁻¹, more preferably 5*10⁵ K*s⁻¹.

The quenching liquid may preferably be added via appropriate inlets or nozzles. The quenching liquid may be directed at an angle α′ of 45 to 135°, preferably 60 to 120° relative to the main stream. The angle of pitch β′ in the equatorial plane relative to the main stream is in the range from −90 to 90°, preferably in the range from −30 to 30°.

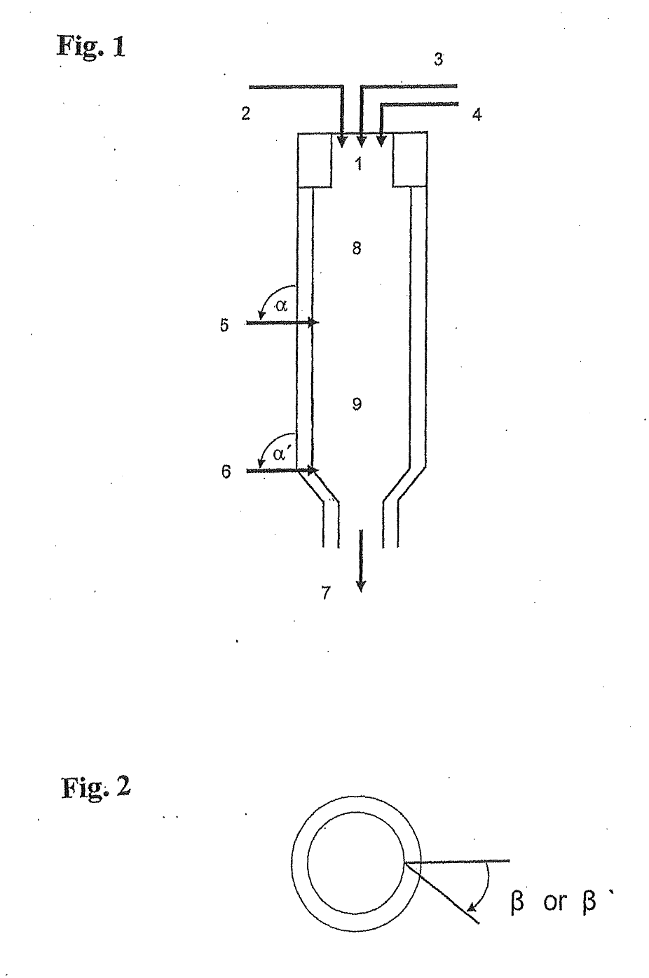

In one possible embodiment, the present invention's apparatus corresponds to the apparatus shown in FIG. 1.

The reference signs in FIG. 1 have the following meanings:
1 metering and mixing appliance
2 inlet for O₂-containing gas
3 inlet for core precursor compound
4 inlet for fuel
5 inlet for envelope precursor compound
6 inlet for coolant
7 outlet for product and off-gases
8 reaction zone to form the core
9 reaction zone to form the envelope

The reactor is equipped at the top in the burner region with a main nozzle (1) via which a liquid titanium precursor compound (3), for example as a solution in an organic solvent, is atomized with air (2) and burned. Optionally, an outer nozzle ring (diffusion burner) can supply preheated air and a combustion gas (4) (for example methane, ethylene) to start up, to reach high reactor temperatures or to reduce baked-on deposits. The titanium precursor compound is converted to TiO₂ in reaction zone (8) in the main stream thus formed. In the middle region, a liquid silicon precursor compound is conveyed into a vaporizer, where it is mixed with preheated nitrogen and passed via a ring-shaped arrangement of openings (5) into the reaction space, so that the vaporized silicon precursor compound meets the stream of the atomized titanium precursor compound at right angles. In reaction zone (9), the silicon precursor compound is reacted in the main stream to form SiO₂. Then, the reaction mixture is rapidly cooled with gaseous room temperature nitrogen in the quench region (6). The resulting core-envelope nanoparticles and off-gases can be allowed to escape through the outlet (7) and collected, respectively.

FIG. 2 shows the cross section through the reaction space to illustrate the angle of pitch β or β′ in the equatorial plane relative to the main stream.

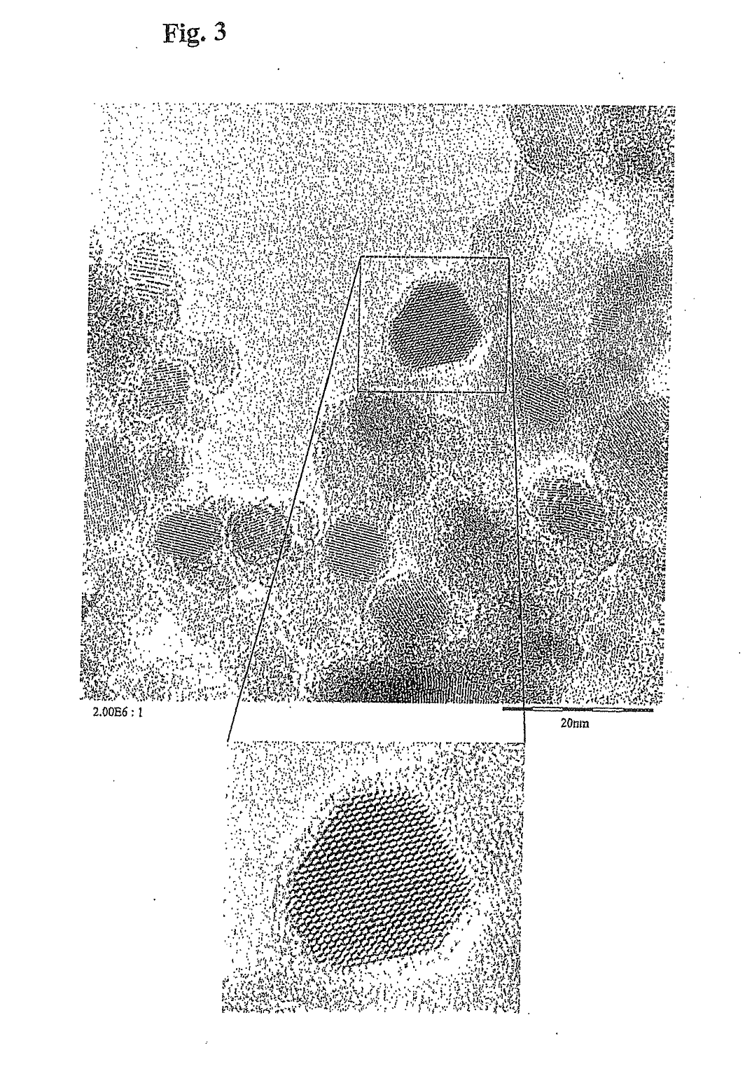

FIG. 3 shows a TEM picture of a core-envelope nanoparticle obtained via the present invention's process.

The present invention will now be more particularly described with reference to examples.

1. Production of TiO₂—SiO₂ nanoparticles

### EXAMPLES 1 TO 5

The main nozzle is supplied with 0.3 to 0.4 kg*h⁻¹ of titanium dioxide precursor compound solution (made up using 284 g of tetraisopropyl orthotitanate (TTiP) and 716 g of xylene per kg of solution). In addition, 3.8 standard m³*h⁻¹ of air flow into the burner region. Additional fuels, for example methane for the nozzle ring (2) are not used. After ignition with a hydrogen ignition burner only used for starting up, a flame stabilizes in the reactor. A stream of 0 to 2.5 g*h⁻¹ of silicon dioxide precursor compound hexamethyl disiloxane (HMDS) is mixed with 0.80 standard m³*h⁻¹ of nitrogen, vaporized at 130° C. and passed into the reactor. The reaction mixture is cooled in the quenching region to 250 to 200° C. by 25 standard m³*h⁻¹ of nitrogen.

A membrane filter collects titanium dioxide coated with silicon dioxide as a fine powder having particle sizes of 5 to 100 nm (determined from TEM pictures).

The individual runs are recited in table 1:

TABLE 1

| | | | | | Reactor | | | | T after | Pressure |
|---|---|---|---|---|---|---|---|---|---|---|
| | TTiP sol. | Air | Methane | N₂ Quench | temp. | HMDS mass stream | Silicon quantity | Residual O₂ | quench | [bar |
| No. | [kg * h⁻¹] | [Nm³ * h⁻¹] | [Nm³ * h⁻¹] | [Nm³ * h⁻¹] | [° C.] | [g * h⁻¹] | [mol Si/mol Ti in %] | [vol %] | [° C.] | abs.] |
| 1 | 0.34 | 3.8 | 0 | 25 | 1100 | 0.50 | 2 | 4-5 | 240 | 1.1 |
| 2 | 0.34 | 3.8 | 0 | 25 | 1200 | 1.0 | 4 | 4-5 | 290 | 1.1 |
| 3 | 0.34 | 3.8 | 0 | 25 | 1250 | 1.5 | 6 | 4-5 | 300 | 1.1 |
| 4 | 0.30 | 3.8 | 0 | 25 | 1150 | 2.0 | 8 | 4-5 | 270 | 1.1 |
| 5 | 0.35 | 3.8 | 0 | 25 | 1200 | 2.5 | 10 | 4-5 | 280 | 1.1 |

Explanations:
TTiP = tetraisopropyl orthotitanate,
air = air by atomizer nozzle, support burner and ignition burner,
HMDS = hexamethyldisiloxane

2. Characterization of SiO₂-Coated TiO₂ Nanoparticles

The layer thickness of the SiO₂ envelope is determined by means of TEM pictures via an FEG-TEM (Field Emission Gun—Transmission Electron Microscopy) method. The crystal form of the crystalline TiO₂ is determined via SAD (Selected Area Diffraction). The silicon concentration is detected in EDXS (Energy Dispersive X-Ray Spectroscopy) analyses and the silicon weight percent is confirmed via elemental analysis. The porosity of the SiO₂ layer is measured via XPS (X-Ray Photo Electron Spectroscopy—ESCA Electron Spectroscopy for Chemical Analysis). Table 2 shows the results:

TABLE 2

| | | Layer thickness | | |
|---|---|---|---|---|
| Example | Amount of Si precursor | [nm] | Porosity | Si wt % |
| Example 1 | 2 mol % of Si | 1-2 | 11.9 | 1.1 |
| Example 2 | 4 mol % of Si | 1-2 | 23.8 | 1.9 |
| Example 3 | 6 mol % of Si | 1-2 | 33.0 | 3.5 |
| Example 4 | 8 mol % of Si | 1-3 | 23.1 | 4.2 |
| Example 5 | 10 mol % of Si | 1-3 | — | — |

3. Determination of Photocatalytic Activity

3.1 Noxiant Degradation

The photoactivities of the powders produced are determined via the rate of photocatalytic degradation of the chlorinated hydrocarbon dichloroacetic acid (DCA) in suspension.

The total length of the runs to test the rate of photocatalytic degradation of DCA under UV irradiation in aqueous solution is 24 hours. UV light intensity is 1 mW/cm².

The pH of the suspension is adjusted to 3 with aqueous sodium hydroxide solution. The temperature in the reactor is in the range from 20 to 30° C. DCA concentration is 20 mmol/L and photocatalyst concentration is 3 g/L. The rate of degradation (ppm/h) can be determined by determining the pH after 24 hours.

Blank tests relating to the degradation of DCA under irradiation are carried out by adding the standard photocatalyst (Degussa P25). Blank tests relating to the degradation of DCA under UV irradiation are also carried out without addition of photocatalyst.

3.2 Polymer Degradation

The rate of photocatalytic degradation of an organic matrix is measured via GC measurements in the polymer suspension into which the photocatalyst is introduced.

The total length of the runs to test the rate of photocatalytic degradation under daylight irradiation (Suntest, 1 mW/cm² UV intensity) is 700 hours.

The photocatalyst is stirred into a polymer suspension (for example Squalen®). The concentration of the photocatalyst is 0.25% by weight. Percentage degradation of the polymer suspension can be determined by determining the GC spectrum.

Blank tests relating to the degradation of the polymers under irradiation are carried out by adding the standard photocatalyst (Degussa P25).

Blank tests relating to the degradation of the polymers under irradiation are also carried out without addition of photocatalyst.

The results are recited in tables 3 and 4.

TABLE 3
Noxiant degradation

| | | Degradation rate |
|---|---|---|
| Example | Catalyst | [ppm TOC/h] |
| Blank test 1 | none | 0 |
| Blank test 2 | P 25 | 4.34 |
| Example 1 | 2 mol % of Si | 3.96 |
| Example 2 | 4 mol % of Si | 3.62 |
| Example 3 | 6 mol % of Si | 3.74 |
| Example 4 | 8 mol % of Si | 3.72 |
| Example 5 | 10 mol % of Si | 3.73 |

TOC is total organic carbon

TABLE 4
Polymer degradation

| | | | Ratio |
|---|---|---|---|
| | | Polymer degradation | degradationₙₒₓᵢₐₙₜ/ |
| Example | Catalyst | difference¹ [%] | degradation_{polymer} |
| Blank | none | 0 | 0 |
| test 1 | | | |
| Blank | P 25 | 2.53 | 1.7 |
| test 2 | | | |
| Example 1 | 2 mol % of Si | 0.34 | 11.7 |
| Example 2 | 4 mol % of Si | 0.28 | 12.9 |
| Example 3 | 6 mol % of Si | 1.34 | 2.8 |
| Example 4 | 8 mol % of Si | 1.03 | 3.6 |
| Example 5 | 10 mol % of Si | 1.38 | 2.7 |

¹The difference in question is the degradation of the polymer by UV radiation without catalyst (blank test 1) relative to degradation of the polymer in the presence of the individual catalysts.

1.-15. (canceled)

16. A process for producing coated nanoparticles comprising a core composed of at least one first substance and at least one envelope at least partly surrounding the core and composed of at least one second substance, in a streaming system, said process comprising the steps of:
(A) providing a main stream composed of a reaction gas or aerosol comprising at least one precursor compound of the at least one first substance present in the core of the coated nanoparticle,
(B) converting by thermal reaction in the main stream the at least one precursor compound present in the reaction gas or aerosol of step (A) into the corresponding at least one first substance to form the core of the nanoparticles to be produced,
(C) adding in a cross stream with regard to the main stream from step (B) a further reaction gas or aerosol comprising at least one precursor compound of the at least one second substance present in the at least one envelope,
(D) converting by thermal reaction in the main stream the at least one precursor compound present in the reaction gas or aerosol of step (C) into the corresponding at least one second substance to form the at least one envelope of the nanoparticles to be produced, and
(E) rapidly cooling the nanoparticles obtained in step (D), by adding a coolant to the main stream, wherein the rate of cooling in step (E) is at least 10⁴ K*s⁻¹.

17. The process according to claim 16, wherein the core of the nanoparticles comprises at least one metal or semimetal oxide and the at least one envelope of the nanoparticle comprises at least one further metal or semimetal oxide.

18. The process according to claim 16, conducted at a temperature of 600 to 2500° C. in the zone, in which thermal reaction of the precursor compounds to the corresponding metal- or semimetal oxide present in the core takes place.

19. The process according to claim 18, wherein the temperature is constant in the entire zone, in which thermal reaction of the precursor compounds to the corresponding metal- or semimetal oxide present in the core takes place.

20. The process according to claim 16, wherein the coolant in step (E) is a gas or a liquid.

21. The process according to claim 16, wherein the nanoparticles obtained are removed as a powder or dispersion after step (E).

22. Nanoparticles wherein >70% of the particle sizes are within just 20 nm of the average particle size, obtainable by the process according to claim 16.

23. Nanoparticles comprising a nonporous core composed of at least one first substance and at least one porous envelope at least partly surrounding the core and composed of at least one second substance, characterized by their ratio of more than 1.8 for their photoactivity with regard to noxiant degradation to photoactivity with regard to polymer degradation.

24. The nanoparticles according to claim 23, wherein the nanoporous core of the nanoparticles comprises at least one metal or semimetal oxide and the at least one envelope of the nanoparticle comprises at least one further metal or semimetal oxide.

25. The nanoparticles according to claim 24, wherein the core comprises at least one metal or semimetal oxide of an element selected from the group consisting of V, Ti, Zr, Ce, Mo, Bi, Zn, Mn, Si, Ba, Au, Ag, Pd, Pt, Ru, Rh, La and mixtures thereof and the at least one envelope comprises at least one further metal or semimetal oxide of an element selected from the group consisting of V, Ti, Zr, Ce, Mo, Bi, Zn, Mn, Si, Ba, Au, Ag, Pd, Pt, Ru, Rh, La and mixtures thereof.

26. The nanoparticles according to claim 24, wherein the nonporous core consists of TiO₂ and the porous envelope consists of SiO₂.

27. The nanoparticles according to claim 22, wherein the core has a diameter of not more than 1 μM and the envelope has a thickness of not more than 10 nm.

28. The method of using nanoparticles according to claim 22 in photocatalysis.

29. An apparatus for carrying out the process according to claim 16, comprising in a tubular reactor
a unit for feeding the reaction gas or aerosol comprising at least one precursor compound of the at least one first substance present in the core and forming a main stream in the tubular reactor,
a unit for thermally reacting the at least one precursor compound present in this reaction gas to convert it into the at least one first substance present in the core,
a unit for feeding the reaction gas or aerosol comprising at least one precursor
compound of the at least one second substance present in the at least one envelope, in a cross stream with regard to the main stream, and
a unit for rapidly cooling the nanoparticle obtained.

30. The apparatus according to claim 29, having a diameter to length ratio of the tubular reaction space in the range from ½ to 1/10.
